(19) United States
(12) Patent Application Publication
(10) Pub. No.: US 2025/0392098 A1
(43) Pub. Date: Dec. 25, 2025

(54) SYSTEM AND METHOD FOR LASER LIGHT SOURCE CONTROL

(71) Applicant: Texas Instruments Incorporated, Dallas, TX (US)

(72) Inventors: Alexander Lyubarsky, Dallas, TX (US); Samuel Martin, Dallas, TX (US); Meng-Che Li, West District (TW)

(21) Appl. No.: 19/059,522

(22) Filed: Feb. 21, 2025

Related U.S. Application Data
(60) Provisional application No. 63/661,807, filed on Jun. 19, 2024.

(51) Int. Cl. H01S 5/042; G03B 21/20; H01S 5/40

(52) U.S. Cl. CPC H01S 5/0428; G03B 21/2013; G03B 21/2033; G03B 21/208; H01S 5/4087

(57) ABSTRACT

A laser controller can be configured to, during a first time period, output a first control signal specifying a first average non-zero intensity level at which a first laser is instructed to produce first laser light of one color, during a second time period, output the first control signal specifying a second average non-zero intensity level, lower than the first average non-zero intensity level, for the first laser light, during at least a portion of the first time period, output a second control signal specifying a third average non-zero intensity level at which a second laser instructed is to produce second laser light of a different color, and during at least a portion of the second time period, output the second control signal specifying a fourth average non-zero intensity level, higher than the second and third average non-zero intensity levels, for the second laser light.

### CROSS-REFERENCE TO RELATED APPLICATIONS

This application claims the benefit of and priority to U.S. Provisional Patent Application No. 63/661,807 titled “METHOD OF DRIVING MULTI-PRIMARY LASER LIGHT SOURCE FOR SPECKLE REDUCTION AND BRIGHTNESS IMPROVEMENT” and filed on Jun. 19, 2024, which application is hereby incorporated herein by reference in its entirety.

### TECHNICAL FIELD

This description relates to light projectors, and more particularly, to control systems and methods for laser-based light sources.

### BACKGROUND

Light projection systems using laser light sources, rather than light emitting diodes are growing in popularity. However, there are several challenges associated with the implementation of laser-based light projection systems. For example, laser speckle, a phenomenon that is known to cause a shimmery effect when an image is projected onto a surface or screen, can reduce image quality. In addition, while some laser light projection systems can have a wide color gamut, the narrow emission bands of individual color lasers (red, green, and blue) can create highly saturated colors that appear unnatural. Furthermore, it can be difficult to implement driving schemes for laser light sources that can achieve sufficient brightness control. Thus, a number of non-trivial issues remain with respect to laser-based light projection systems.

### SUMMARY

According to one example, a laser controller is configured to: during a first time period, output a first control signal specifying a first average non-zero intensity level at which a first laser is instructed to produce first laser light having a first color; during a second time period, output the first control signal specifying a second average non-zero intensity level at which the first laser is instructed to produce the first laser light having the first color, the second average non-zero intensity level being lower than the first average non-zero intensity level; during at least a portion of the first time period, output a second control signal specifying a third average non-zero intensity level at which a second laser is instructed to produce second laser light having a second color; and during at least a portion of the second time period, output the second control signal specifying a fourth average non-zero intensity level at which the second laser is instructed to produce the second laser light having the second color, the fourth average non-zero intensity level being higher than the second and third average non-zero intensity levels and the second color being different than the first color.

According to another example, a light projection system comprises a laser light source configured to emit a laser beam, the laser light source including a first laser configured to emit first laser light in a first spectral range and a second laser configured to emit second laser light in a second spectral range different from the first spectral range; and a laser controller coupled to the laser light source and configurable to control a color gamut of the laser beam by controlling respective intensities of the first laser light emitted by the first laser and the second laser light emitted by the second laser. In one example, the laser controller is configurable to (i) produce a first control signal to operate the first laser to emit the first laser light with a first non-zero average intensity level for a first time period and with a second average non-zero intensity level for a second time period, the first average non-zero intensity level being higher than the second average non-zero intensity level, and (ii) produce a second control signal to operate the second laser to emit the second laser light with a third average non-zero intensity level for at least a portion of the first time period and with a fourth average non-zero intensity level for at least a portion of the second time period, the fourth average non-zero intensity level being higher than the second and third average non-zero intensity levels. In one example, the light projection system further comprises a spatial light modulator optically coupled to the laser light source and configured to project an image based on the laser beam.

According to another example, a method of operating a multi-color laser light source comprises: emitting, with a first laser of the multi-color laser light source, first laser light in a first spectral range with a first average non-zero intensity level for a first portion of a time period and with at least a second average non-zero intensity level for a second portion of the time period, wherein the first average non-zero intensity level is higher than the second average non-zero intensity level; emitting, with a second laser of the multi-color laser light source, second laser light in a second spectral range with a third average non-zero intensity level for a third portion of the time period and with at least a fourth average non-zero intensity level for a fourth portion of the time period, wherein the third average non-zero intensity level is higher than the second and fourth average non-zero intensity levels, wherein the third portion of the time period at least partially overlaps with the second portion of the time period; and emitting, with a third laser of the multi-color laser light source, third laser light in a third spectral range with a fifth average non-zero intensity level for a fifth portion of the time period and with at least a sixth average non-zero intensity level for a sixth portion of the time period, wherein the fifth average non-zero intensity level is higher than the second, fourth, and sixth average non-zero intensity levels, wherein the fifth portion of the time period at least partially overlaps with the second and fourth portions of the time period.

### BRIEF DESCRIPTION OF THE DRAWINGS

FIG. 1A is a block diagram of a light projection system, according to an example.

FIG. 1B is a block diagram of the light projection system of FIG. 1A, according to an example.

FIG. 2 is a block diagram of the light projection system of FIGS. 1A and/or 1B, according to an example.

FIG. 3A is a block diagram of the light projection system of FIGS. 1A and/or 1B, according to an example.

FIG. 3B is a block diagram of the light projection system of FIGS. 1A and/or 1B, according to another example.

FIG. 4A is a set of graphs illustrating light output from a laser light source over time, according to an example.

FIG. 4B is a set of graphs illustrating light output from a laser light source over time, according to another example.

FIG. 4C is a set of graphs illustrating light output from a laser light source over time, according to another example.

FIG. 4D is a graph illustrating light output from a laser light source over time, according to another example.

FIG. 5A is a graph illustrating a color gamut for a laser light source, according to an example.

FIG. 5B is a graph illustrating a color gamut for a laser light source, according to another example.

FIG. 6A is a flow diagram of a method of controlling a multi-color laser light source, according to an example.

FIG. 6B is a flow diagram of a method of operating a multi-color light source, according to an example.

### DETAILED DESCRIPTION

Techniques are described for controlling a multi-primary laser light source (e.g., one that comprises multiple laser diodes that individually emit light of different primary colors, such as red, green, and/or blue) to reduce, or desaturate, the color gamut, while also increasing the brightness of the projected light and reducing laser speckle. Accordingly, certain examples provide a method of driving a multi-color laser light source in which multiple lasers of different colors are operated simultaneously to improve brightness and reduce laser speckle. For example, as described in more detail below, a laser controller can be configured to drive a multi-color laser light source such that, during a first color sequence in which a first laser is controlled to emit light of a first color with relatively high optical power, a second laser is controlled to emit light of a second color with relatively low optical power, and during a second color sequence in which the second laser is controlled to emit light of the second color with relatively high optical power, the first laser is controlled to emit light of the first color with relatively low optical power. This control arrangement can be extended to include additional colors, as described further below. Reference to “high” or “low” optical power of one laser in the light source is relative to the optical power of another laser in the light source.

In one example, a laser controller is configured to, during a first time period of a sequence period, output a first control signal configured to specify a first average (also referred to as effective) non-zero intensity level at which a first laser is to produce first laser light having a first color. During a second time period of the sequence period, the laser controller is configured to output the first control signal configured to specify a second average non-zero intensity level at which the first laser is to produce the first laser light having the first color. The second average non-zero intensity level is lower than the first average non-zero intensity level. The laser controller can be further configured to, during at least a portion of the first time period, output a second control configured to specify a third average non-zero intensity level at which a second laser is to produce second laser light having a second color, and during at least a portion of the second time period, output the second control signal configured to specify a fourth average non-zero intensity level at which the second laser is to produce the second laser light having the second color. The fourth average non-zero intensity level may be higher than the second and third average non-zero intensity levels, and the second color may be different than the first color.

### General Overview

Light projection systems can be used in a wide variety of different display applications. As noted above, light projection systems that use lasers (e.g., laser diodes) as the emitting light source are becoming increasingly popular. However, there are numerous challenges associated with the implementation of laser-based systems. For example, laser speckle, which may be caused by optical interference of the coherent laser beam with the texture of the surface onto which the beam is projected, can degrade the quality of the projected image. Additionally, as described above, although some laser projection systems have a wide color gamut, the narrow emission wavelength ranges of individual-color lasers (e.g., red, green, and blue) can create very saturated colors that can appear unnatural. This effect can be particularly noticeable in the red color region due to the relatively long wavelengths (e.g., 640-650 nanometers (nm)) and narrow-band emission of a red laser. Although some laser projection systems employ color correction algorithms, these algorithms cannot adjust individual laser power, and therefore, the brightness of the projected beam is reduced when reducing the color gamut around a given white point. Furthermore, driving individual lasers of a multi-color laser light source to operate sequentially within a display frame period can also involve complex control/driving schemes. Thus, several non-trivial challenges remain with respect to implementing laser-based projection systems.

To address these and/or other issues, examples described herein provide a control methodology whereby multiple lasers, emitting light of different colors (e.g., red, green, blue), can be driven at the same time during the various color sequences within a display frame. For example, during a red color sequence, in which one or more red lasers may be operated to produce an emission with relatively high optical power, small amounts of blue and/or green light can be inserted by operating one or more blue and/or green lasers, respectively, to produce emissions with relatively low optical power. Similarly, during a green color sequence, small amounts of red and/or blue light can be added, and likewise, during a blue color sequence, small amounts of red and/or green light can be added. By driving multiple lasers of different colors during the same time period, the resulting wavelength diversity can decrease the coherence of the output beam, which can reduce or improve laser speckle. In addition, by adding small amounts of other wavelengths during a particular color sequence (also referred to as a color channel), the color gamut can be reduced or “desaturated,” while the overall brightness of the projected beam is increased due to the addition of optical power from other lasers for a given color channel. In some examples, dynamic color gamut adjustment can be performed “on-the-fly” or in real time by adjusting the amount of other color(s) added at any given time. This approach can useful in a variety of applications, including high dynamic range (HDR) display/projection devices and applications. In some examples, dynamic color gamut adjustment can be per performed based on the content of the image to be displayed. For example, this approach may be used to add localized brightness peaking in HDR and other applications.

Accordingly, in some examples, a method of operating a multi-color laser light source comprises emitting, with a first laser of the multi-color laser light source, first laser light in a first spectral range (e.g., of a first color) with a first average non-zero intensity level for a first portion of a time period and with at least a second average non-zero intensity level for a second portion of the time period. The first average non-zero intensity level may be higher than the second average non-zero intensity level. The method may further comprise emitting, with a second laser of the multi-color laser light source, second laser light in a second spectral range (e.g., of a second color) with a third average non-zero intensity level for a third portion of the time period and with at least a fourth average non-zero intensity level for a fourth portion of the time period. The third average non-zero intensity level may be higher than the second and fourth average non-zero intensity levels. Further, the third portion of the time period may at least partially overlap with the second portion of the time period. In some examples, the method further comprises emitting, with a third laser of the multi-color laser light source, third laser light in a third spectral range (e.g., of a third color) with a fifth average non-zero intensity level for a fifth portion of the time period and with at least a sixth average non-zero intensity level for a sixth portion of the time period. The fifth average non-zero intensity level may be higher than the second, fourth, and sixth average non-zero intensity levels. Further, the fifth portion of the time period may at least partially overlap with the second and fourth portions of the time period. Certain examples provide a laser controller configured to drive a multi-color laser source according to examples of the method described above.

These and other aspects are described in more detail below.

### Example System Architecture

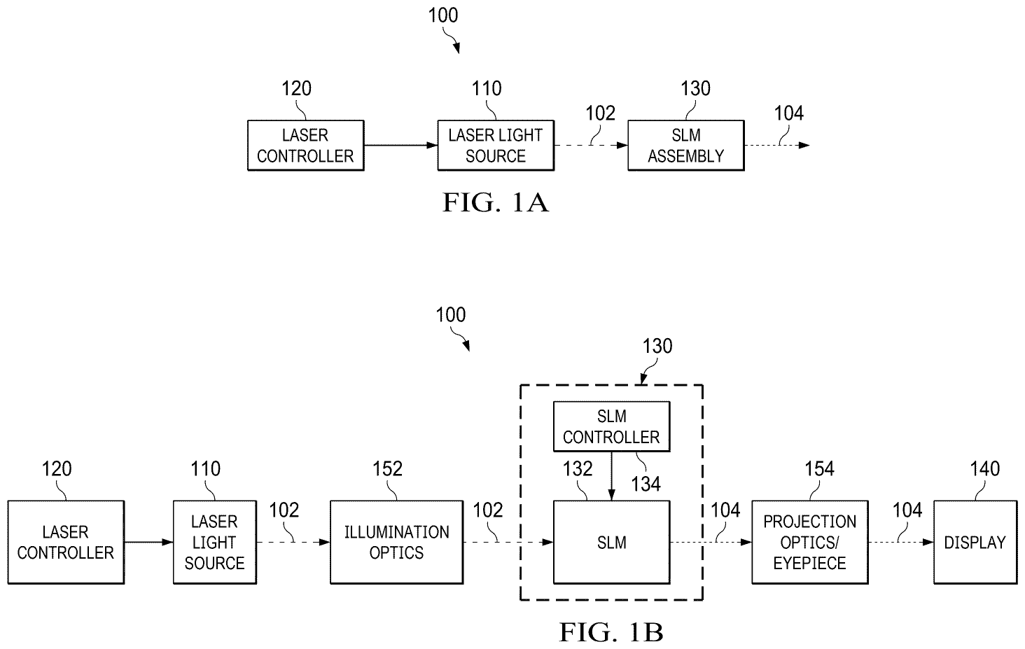

FIG. 1A is a block diagram of a light projection system 100, according to an example. In the illustrated example, the light projection system 100 includes a laser light source 110, a laser controller 120, and a spatial light modulator assembly 130. The laser controller 120 can be configured to control the laser light source 110 to emit an illumination beam 102. The laser light source 110 and the spatial light modulator assembly 130 are optically coupled and arranged such that the illumination beam 102 illuminates a spatial light modulator of the spatial light modulator assembly 130, which modulates the illumination beam 102 to produce a projection beam 104. According to certain examples, the laser controller 120 implements a control scheme to control the laser light source 110 to emit the illumination beam 102 having a desaturated color gamut and higher brightness, and to reduce laser speckle effects in the projection beam 104, as described further below.

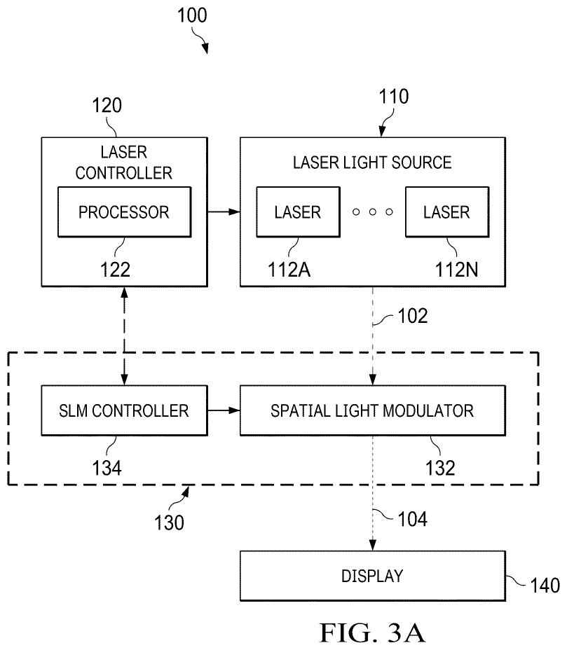

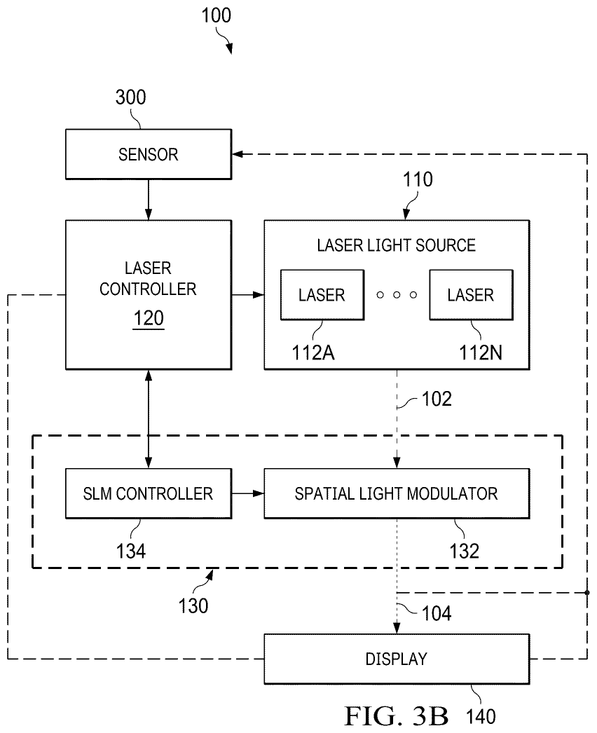

Referring to FIG. 1B, there is illustrated an example of the light projection system 100. As illustrated, the light projection system 100 may include a display 140 to which the projection beam 104 is directed. The display 140 may include a device with a display screen (e.g., a television, computing device, smartphone, etc.) or a display surface (e.g., a canvas or other projection screen, a wall, a window, a windshield, glasses, a roadway, or some other surface onto which images can be projected for viewing). As also shown, the spatial light modulator assembly 130 includes a spatial light modulator (SLM) 132 and an SLM controller 134. The spatial light modulator 132 can be a micro-electromechanical device (e.g., a digital micromirror device (DMD)), a liquid crystal based display device, or another projection device. The SLM controller 134 can be configured to write image data representing an image to the spatial light modulator 132 and to control the spatial light modulator 132 to display, or project, the image when the spatial light modulator 132 is illuminated by the illumination beam 102 from the laser light source 110. The image projected by the spatial light modulator 132, represented by the projection beam 104, for example, may displayed on/by the display 140. In some examples, to produce a desired projection beam 104, the laser light source 110 and the spatial light modulator 132 may be operated together in a synchronized manner. For example, in some instances, the SLM controller 134 can be configured to write the image data to the spatial light modulator 132 using pulse width modulation (PWM) timing signals. In some such examples, the SLM controller 134 may be further configured to synchronize the PWM timing signals for the spatial light modulator 132 with enable timing signals of the laser controller 120 for the laser light source 110 such that the laser light source 110 can be controlled to appropriately illuminate the spatial light modulator 132. Accordingly, in some examples, the SLM controller 134 and the laser controller 120 may be communicatively coupled, as illustrated in FIGS. 3A and 3B, for example, to achieve appropriate synchronization between the laser light source 110 and the SLM 132. In other examples, the laser controller 120 and the SML controller 134 may be implemented as a single controller that performs both functions (e.g., control of the laser light source 110 and control of the SLM 134).

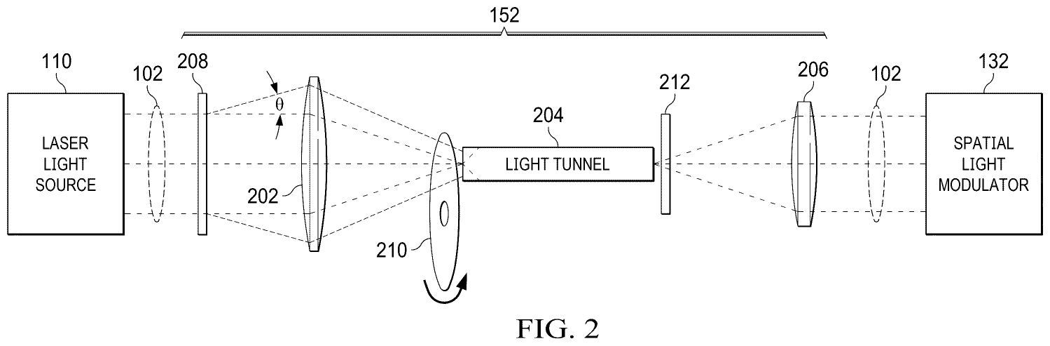

Continuing with the example of FIG. 1B, the light projection system 100 may include illumination optics 152 positioned in an optical path between the laser light source 110 and the spatial light modulator 132. Thus, the spatial light modulator 132 and the laser light source 110 may be optically coupled via the illumination optics 152, such that the illumination optics 152 directs the illumination beam 102 to the spatial light modulator 132. The illumination optics 152 may include one or more lenses, mirrors, and/or other optical elements that condition (e.g., focus, collimate, diffuse, homogenize, perform chromatic and/or spatial aberration corrections, etc.) the illumination beam 102 emitted by the laser light source 110 and direct the illumination beam 102 onto the spatial light modulator 132. Examples of some optical elements that may be part of the illumination optics 152 are described below with reference to FIG. 2. In addition, the light projection system 100 may include projection optics 154 (which in some examples includes an eyepiece, depending on the application of the light projection system 100) that condition the projection beam output from the spatial light modulator 132 and direct the projection beam 104 to the display 140. For example, the projection optics 154 may include one or more mirrors and/or lenses. Thus, the display 140 may be optically coupled to the spatial light modulator 132 via the projection optics 154.

FIG. 2 is a diagram illustrating various components that may form part of the illumination optics 152, according to some examples. The illumination optics 152 may include a first optical element 202 that images the illumination beam 102 output from the laser light source 110 onto a light tunnel 204. The illumination optics 152 may further include a second optical element 206 that collimates light output from the light tunnel 204 and directs the illumination beam 102 onto the spatial light modulator 132. In the example illustrated in FIG. 2, the first and second optical elements 202, 206 are represented by lenses. However, either or both of the first and/or second optical elements 202, 206 individually may comprise one or more lenses and/or one or more mirrors. The light tunnel 204 conveys the illumination beam 102 along at least a portion of the optical path between the laser light source 110 and the spatial light modulator 132. In some examples, the light tunnel 204 includes a waveguide or integrator rod configured to homogenize the illumination beam 102. In other examples, the light tunnel 104 may be replaced with a different homogenizing optical element, such as a “fly's eye” array, for example. The illumination optics 152 may further comprise one or more optical elements for illumination despeckling to reduce laser speckle effects in the displayed projection beam 104.

For example, the illumination optics 152 may include an entrance static diffuser 208 that is configured to expand the spot size of the illumination beam 102 at the entrance to the light tunnel 204. This may provide spatial diversity in the illumination beam 102, which may reduce laser speckle. As illustrated, the entrance static diffuser 208 may be positioned between the laser light source 110 and the first optical element 202. In other examples, the entrance static diffuser 208 may be positioned between the first optical element 202 and the entrance to the light tunnel 204. Alternatively, in examples in which the first optical element 202 comprises multiple lenses and/or mirrors, the entrance static diffuser 208 may be positioned between individual components of the first optical element 202.

In some examples, the illumination optics 152 includes a moving diffuser 210 that is configured to expand light within the pupil of the illumination optics 152. This may provide angular diversity in the illumination beam 102, which may also reduce laser speckle. The moving diffuser 210 may be a rotating, laterally shifting, or tilting diffuser, for example. Although illustrated as a transmissive diffuser in FIG. 2, in other examples, the moving diffuser 210 can be a reflective diffuser, with appropriate modifications to the optical arrangement of components of the illumination optics 152, as will be appreciated by those skilled in the art, given the benefit of this disclosure. In some examples, the illumination optics 152 includes both the entrance static diffuser 208 and the moving diffuser 210, as illustrated in FIG. 2. In other examples, the illumination optics 152 may include the moving diffuser 210 and omit the entrance static diffuser 208. In some examples, the moving diffuser 210 is positioned proximate an entrance to the light tunnel 204, as illustrated in FIG. 2. In other examples, the moving diffuser 210 may be positioned anywhere between the laser light source 110 and the entrance to the light tunnel 204.

In some examples, the illumination optics 152 includes an exit static diffuser 212 positioned between an exit of the light tunnel 204 and the spatial light modulator 132. In some examples, the exit static diffuser 212 is positioned proximate the exit of the light tunnel 204, as shown in FIG. 2; however, in other examples, the exit static diffuser 212 may be positioned elsewhere in the optical path between the exit of the light tunnel 204 and the spatial light modulator. The exit static diffuser 212 positioned after the light tunnel 204 may help to further homogenize the illumination beam 102 within the pupil of the illumination optics 152. In some examples, the illumination optics 152 includes the exit static diffuser 212 in combination with the entrance static diffuser 208 and/or the moving diffuser 210. In other examples, the illumination optics 152 may include the exit static diffuser 212 and omit the entrance static diffuser 208 and/or the moving diffuser 210.

In some examples, the laser control scheme described below may reduce laser speckle such that one or more of the entrance static diffuser 208, the moving diffuser 210, and/or the exit static diffuser 212 can be omitted, with the light projection system 100 still achieving sufficient image quality for a given application. In other examples, the laser control scheme described below can be implemented in a light projection system 100 that includes any one or more of the entrance static diffuser 208, the moving diffuser 210, the exit static diffuser 212, and/or other optical components configured to reduce laser speckle (optionally in addition to other functions).

Referring to FIG. 3A, in some examples, the laser light source 110 includes a plurality of lasers 112 (individually identified as lasers 112A-112N). Individual lasers 112 may emit light in particular wavelength ranges and of different colors. For example, the laser light source 110 may include at least three lasers 112 configured to emit blue, red, and green light, respectively. In some examples, the laser light source 110 may include multiple lasers 112 configured to emit light of a particular color. For example, the laser light source 110 may include one laser 112 for each color (e.g., red, green, and blue), or more than one laser 112 for some or all colors. Using multiple lasers 112 for a particular color can reduce laser speckle by providing wavelength diversity in the illumination beam 102. For example, the laser light source 110 may include multiple lasers 112 that emit light of similar wavelengths within the wavelength range that corresponds to a single color. For example, lasers 112 configured to emit light with wavelengths of 640 nanometers (nm) and 645 nm both emit in the red region of the visible spectrum (and may be referred to as red lasers). The use of such, or similar, lasers in combination provides wavelength diversity in the red channel, which reduces the coherence of the light and thus may improve laser speckle. A similar approach may be used for blue, green, and/or other colors.

It will be appreciated that in some examples, the light projection system 100 may include the use of multiple lasers for any one or more colors in addition to any one or more of the components described above (with reference to FIG. 2) for illumination despeckling. In other examples, the use of multiple lasers for any one or more colors may reduce or obviate the need for one or more of the entrance static diffuser 208, the moving diffuser 210, the exit static diffuser 212, and/or other optical components configured to reduce laser speckle. Furthermore, examples of the laser control scheme described herein may be implemented in systems that use a single laser 112 for emitting light of a particular color, and/or multiple lasers for emitting light of any one or more particular colors.

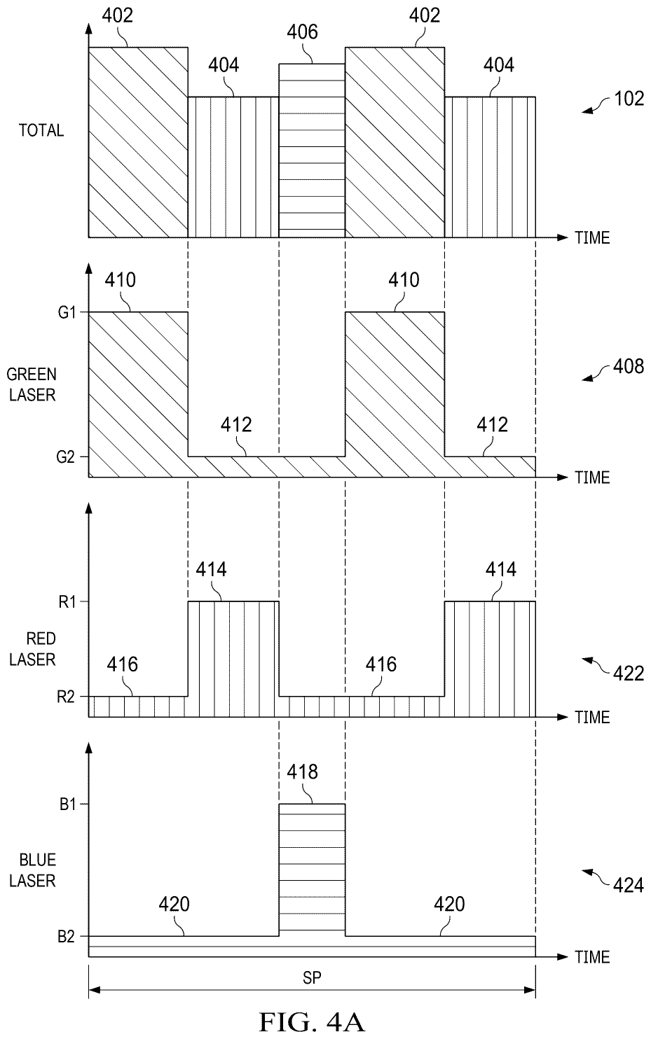

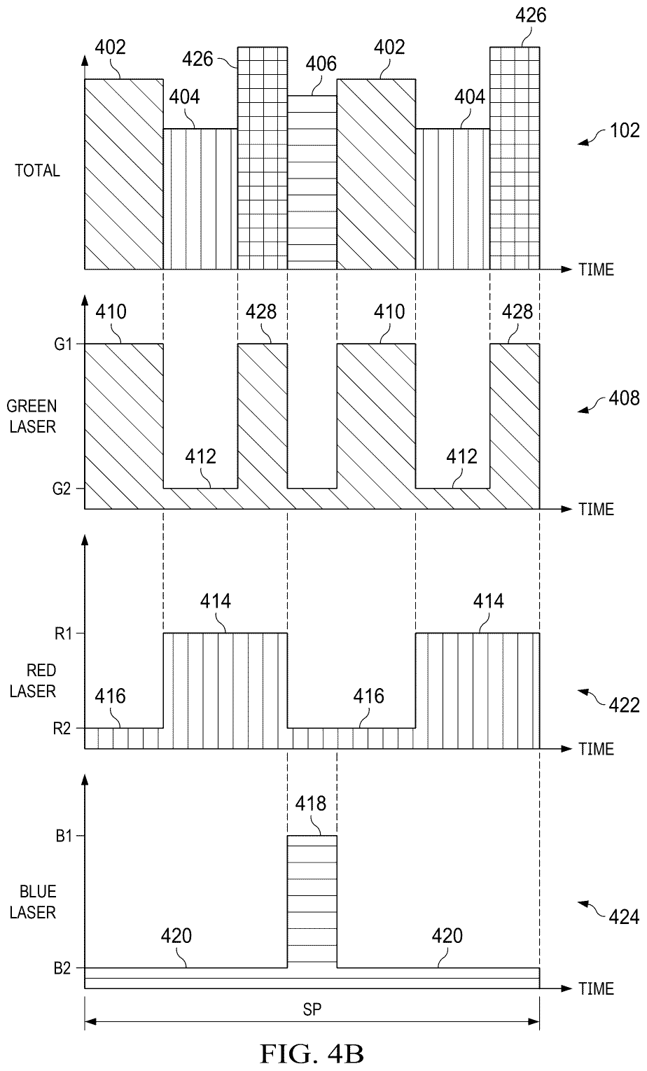

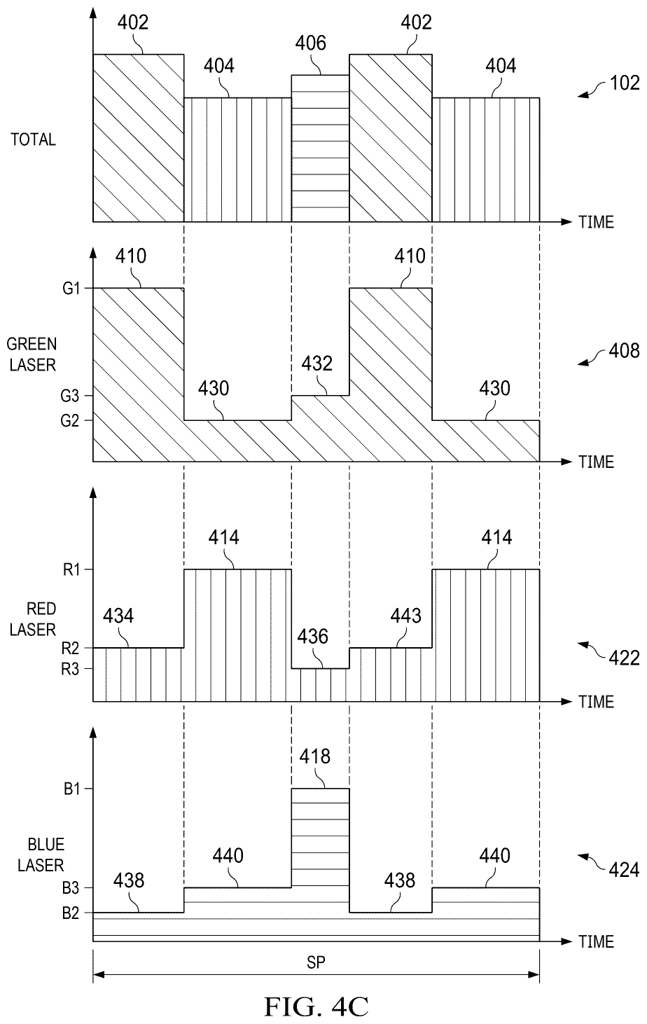

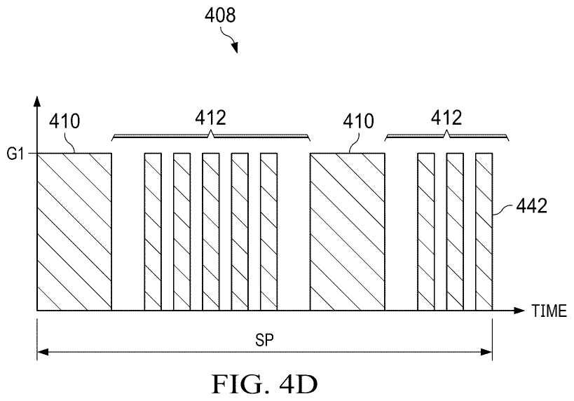

According to certain examples, the lasers 112 of the laser light source 110 are operated in a time sequential manner to produce pulses of light of different colors that together form the illumination beam 102. Over the duration of a sequence period, one or more pulses of light of different colors are emitted by the lasers 112, as described further below with reference to FIGS. 4A-C. These individual color pulses can be integrated over the sequence period to form the illumination beam 102. In some examples, the duration of the sequence period is less than the critical flicker fusion rate, such that an observer of the illumination beam 102 sees a continuous white/gray beam, rather than the individual pulses of different colors. The duration and intensity of the pulses of different colors, in any given sequence period, determine an overall color gamut and white point of the illumination beam 102, as described further below. In some examples, the duration of the sequence period is equal to a frame period, namely the duration for which the spatial light modulator 132 is controlled to project, as the projection beam 104, a single frame of image data to be displayed on the display 140.

The laser controller 120 can be configured to control the duration and/or intensity of the light emitted by the individual lasers 112 to desaturate the color gamut of the illumination beam 102 and to select a desired white point of the illumination beam 102. In some laser systems, the individual lasers are controlled such that when a laser (or laser group) of one color is emitting (e.g., red), the lasers (or laser groups) of other colors (e.g., blue and green) are turned off. In contrast, the laser controller 120 according to examples described herein can be configured to drive the laser light source 110 such that, while the laser(s) of one color are controlled to emit light of that color with relatively high optical power, some or all of the lasers of other colors are controlled to emit light of the other color(s) with varying levels of relatively low optical power. Thus, during any one color sequence or channel, lasers configured to emit other colors can be controlled to add small amounts of those colors to the channel. This simultaneous operation of lasers 112 of multiple colors provides a blending that may reduce color saturation, while also adding wavelength diversity to reduce laser speckle and increasing the brightness of the illumination beam 102.

Examples of this multi-color laser control scheme are described further below with reference to FIGS. 4A-D and 5A-B.

In some examples, the laser controller 120 controls the individual lasers 112 of the laser light source 110 using pulse width modulation signals that control durations of time for which individual lasers 112 emit at either a high optical power level or a low optical power level. In addition, the control signals from the laser controller 120 may specify the intensity (optical power) levels of individual emissions. For example, the laser controller 120 can be configured to, via the control signals, adjust the drive current for individual lasers 112, which adjusts the output intensity of the respective lasers 112. In other examples, a pulse width modulation scheme can be applied to control the effective (also referred to as average) output intensity of the laser emissions. For example, the control signals can be configured to pulse individual lasers 112 rapidly on and off with a duty cycle selected to achieve a desired average power (intensity). This approach may have advantages, particularly for achieving the relatively low-power emissions. Low drive current operation for individual lasers has challenges because, in at least some implementations, the lasers are not stable near threshold current levels. For example, a laser may need a certain threshold drive current to lase, and operating the laser near this threshold (e.g., to achieve a low intensity emission) can result in unstable or unreliable performance from the laser. This challenge can be avoided by pulsing the laser (e.g., using pulse width modulation control signals) with a higher drive current (e.g., well above the lasing threshold), and controlling the duty cycle of the pulses to achieve a particular average output intensity for the emission. It will be appreciated that this pulse width modulation control to achieve a specified output intensity may be independent of further pulse width modulation control to achieve a specified duration of emission by individual lasers 112, as described further below.

In some examples, the laser controller 120 is configured to adjust the control signals to vary the intensity and/or pulse duration of emissions from any one or more of the lasers 112 of the laser light source 110 in response to data that provides information about the color gamut of the illumination beam 102 and/or the projection beam 104. In some examples, the laser controller 120 can be programmed with data specifying a desired color gamut and/or white point for the illumination beam 102, or may receive data specifying this information. Accordingly, the laser controller 120 may include one or more processors 122 capable of causing the laser controller 120 to produce appropriate control signals for the laser light source 110 based on this data. In some examples, the data specifies particular effective/average intensity levels for high and low optical power emissions for the laser(s) 112 of each color. In other examples, the processor 122 may be programmed with, or may access via one or more computer-readable storage media (not illustrated), information that translates a particular while point and/or color gamut into corresponding high and low intensity levels and pulse durations for emissions of different colors from the laser light source.

In some examples, the laser controller 120 can adjust the control signals to the laser light source 110 in response to a feedback or control signal. For example, referring to FIG. 3B, the laser controller 120 can be configured to receive data from a sensor 300 that measures (or otherwise obtains information about) one or more characteristics of the projection beam 104. For example, the sensor 300 may include an optical sensor that is positioned sample the projection beam 104. From measurements obtained by the sensor 300, the color gamut and/or white point of the projection beam 104 can be deduced. If the color gamut and/or white point of the projection beam 104 do not match specifications provided to the laser controller 120, the laser controller 120 may adjust the control signals for one or more of the lasers 112 of the laser light source 110 to alter the color gamut and/or white point. In other examples, the sensor 300 may obtain measurements from the display 140, rather than directly from the projection beam 104. In further examples in which the display 140 includes a display device (such as a TV or computing device, for example), the display 140 may provide a feedback signal to the laser controller 120 that causes the laser controller 120 to adjust color characteristics of the illumination beam 102. For example, a user may change one or more settings on the display 140 that result in a need to change the color characteristics of the projection beam 104. In another example, the sensor 300 may be an embedded sensor in the display 140 that provides information to the laser controller 120 to cause the laser controller 120 to adjust color characteristics of the illumination beam 102. In some examples, such as where the display 140 includes an HDR TV or other HDR display device, the display 140 may provide signals to the laser controller 120 to instruct dynamic adjustment of the color gamut, for example, based on content of the displayed image (as described above) or on one or more settings of the display device. Numerous other variations and/or configurations may be apparent in light of this disclosure and are intended to be part of this disclosure.

In some examples, the laser controller 120 can be configured to detect a sensor signal from the sensor 300, the sensor signal being indicative of at least one parameter of the color gamut of the projection beam 104 and/or the illumination beam 102. In response to the sensor signal, the laser controller 120 can be configured to alter one or more of the control signals for respective one or more individual lasers 112 to adjust the color gamut of the illumination beam 102, which in turn may adjust the color gamut of the projection beam 104, as described above. Thus, the color gamut can be dynamically adjusted. In some examples, the color gamut can be dynamically adjusted based on the content of an image to be displayed, as described above.

### Example Control Methodology

FIG. 4A illustrates a set of graphs showing illumination from the laser light source 110, according to an example. The horizontal axis represents time (in arbitrary units) and the vertical axis represents emission intensity, or optical power (in arbitrary units). In this example, the illumination beam 102 comprises, for a sequence period, Sp, a green color sequence including two green pulses 402, a red color sequence including two red pulses 404, and a blue color sequence including a blue pulse 406. During the green color sequence, an emission 408 from the green laser(s) includes two corresponding high intensity pulses 410 (corresponding in time to the two green pulses 402 of the illumination beam 102). In some examples, during a remainder of the sequence period, or during portions of the sequence period corresponding to the red color sequence and the blue color sequence, the green laser is operated to produce a low intensity emission 412. As described above, this operation is in contrast to systems in which, during the red and blue color sequences, the green laser(s) are turned off, thus producing no emission, rather than the low intensity emission 412 shown in FIG. 4A.

As described above, in some examples, the laser light source 110 includes a single green laser 112, whereas in other examples, the laser light source 110 may include two or more lasers 112 emitting in the green portion of the visible spectrum. These two or more green lasers may emit at the same wavelength or at different wavelengths within the green spectral band (e.g., approximately 495-570 nm). The same applies for red and blue. Accordingly, this description may refer to the green, red, and/or blue “laser;” however, it is to be appreciated that this terminology is intended to include implementations using a single laser per color and implementations using one or more lasers for any color.

Still referring to FIG. 4A, in the illustrated example, during the red color sequence, an emission 422 from the red laser includes two high intensity pulses 414 corresponding in time to the two red pulses 404 of the illumination beam 102. In some examples, during a remainder of the sequence period, or during portions of the sequence period corresponding to the green color sequence and/or the blue color sequence, the red laser is operated to produce a low intensity emission 416. As described above, this operation is in contrast to systems in which, during the green and blue color sequences, the red laser is turned off, thus producing no emission, rather than the low intensity emission 416 shown in FIG. 4A.

Similarly, during the blue color sequence, an emission 424 from the blue laser includes a high intensity pulse 418 corresponding in time to the blue pulse 406 of the illumination beam 102. In some examples, during a remainder of the sequence period, or during portions of the sequence period corresponding to the red color sequence and/or the green color sequence, the blue laser is operated to produce a low intensity emission 420. As described above, this operation is in contrast to systems in which, during the red and green color sequences, the blue laser is turned off, thus producing no emission, rather than the low intensity emission 420 shown in FIG. 4A.

Thus, for the color sequences illustrated in the example of FIG. 4A, the laser controller 120 can be configured to supply control signals to drive the green, red, and blue lasers to produce the emissions 408, 422, and 424, respectively, for one or more sequence periods, Sp. For example, during a first time period of the sequence period, Sp, that corresponds to the time duration of the green color sequence, the laser controller 120 can be configured to output a first control signal for the green laser, the first control signal specifying an average intensity level, G1, at which the green laser is to produce the pulses 410 of the green emission 408. It will be appreciated, that the first time period is not necessarily a single continuous time period, but instead (in the example of FIG. 4A), includes two distinct time portions corresponding to the two green pulses 410. During a second time period of the sequence period, Sp, the laser control outputs the first control signal specifying an average intensity level, G2, at which the green laser is to produce the low intensity emissions 412 of the green emission 408. As described above, the first control signal can be configured to specify the intensity levels G1, G2 either by adjusting the drive current for the green laser or by using pulse width modulation of a set drive current to control average output power (e.g., as described further below with reference to FIG. 4D), or a combination of both. Accordingly, the intensity levels G1, G2 represent average or effective intensity levels of the green emission 408 over the corresponding time durations. However, those average/effective intensity levels can be produced through pulse width modulation of an actual higher-intensity emission/output from the green laser (as described below with reference to FIG. 4D), or by adjusting the drive current of the green laser to produce an output emission with the corresponding actual intensity level.

As illustrated in FIG. 4A, the intensity level G2 is lower than the intensity level, G1. As also illustrated in FIG. 4A, the second time period of the sequence period overlaps in time with the red and blue color sequences, and may, in some examples, constitute a remainder of the sequence period, Sp, for the green laser (e.g., the duration of the sequence period for which the green laser is not emitting the pulses 410 at the intensity level G1). Thus, in some examples, a sum of the first time period and the second time period is equal to the sequence period, Sp.

The laser controller 120 can be further configured to, during a third time period that overlaps in time with at least a portion of the second time period, output a second control signal for the red laser (for example), the second control signal specifying an average intensity level, R1, at which the red laser is to produce the pulses 414 of the red color sequence. Furthermore, the laser controller 120 can be configured to, during a fourth time period that overlaps in time with at least a portion of the first time period (during which the green laser is emitting the pulses 410), output the second control signal specifying an average intensity level, R2, at which the red laser is to produce the low intensity emissions 416 of the red emission 422. As in the case of the green color sequence and as illustrated in FIG. 4A, the third and fourth time periods are not necessarily continuous. Further, the different average/effective intensity levels, R1, R2, of the red emission 422 can be achieved by adjusting the drive current and/or using pulse width modulation. Similarly, the laser controller can be configured to, during a fifth time period of the sequence period, Sp, (e.g., during which the green and red lasers are not emitting the green and red pulses 410, 414, respectively), output a third control signal for the blue laser, the third control signal specifying an average intensity level, B1, at which the blue laser is to produce the pulse 418 of the blue color sequence. Furthermore, the laser controller 120 can be configured to, during at least a portion of the first time period (during which the green laser is emitting the green pulses 410) and/or the third time during which the red laser is emitting the red pulses 414, output the second control signal specifying an average intensity level, B2, at which the blue laser is to produce the low intensity emissions 420 of the blue emission 424. As for the green and red lasers, the different average/effective intensity levels of the blue emission can be achieved by adjusting the drive current and/or using pulse width modulation, as described further below.

Thus, as illustrated in FIG. 4A, under the control of the laser controller 120, the laser light source 110 can be configured to emit the green pulses 410, red pulses 414, and blue pulse 418 during individual time periods or portions of the sequence period, Sp. The pulses 410, 414, 418 correspond to relatively high-intensity emissions from the respective lasers 112. That is, the intensity levels G1, R1, and B1 are higher than any of the intensity levels G2, R2, and B2. When one color is being emitted at the respective high intensity level, G1, R1, or B1, some or all of the other lasers can be controlled to emit at the respective lower intensity levels G2, R2, or B2. In some examples, the low intensity levels G2, R2, and B2 are all averaged non-zero intensity levels. Thus, during each color sequence, relatively small amounts of light from some or all of the other colors can be added to the output illumination. This color blending may increase the brightness of the illumination beam 102 and may also reduce the color gamut.

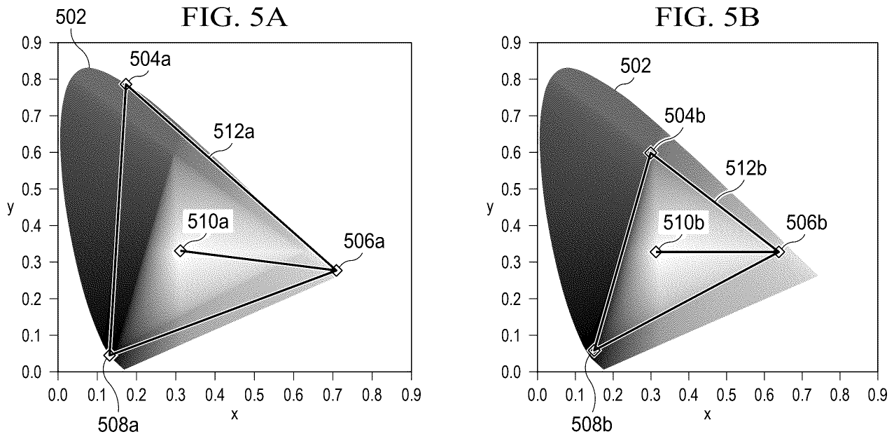

Accordingly, the green pulses 402 in the illumination beam 102 may be of a somewhat different shade or hue of green than are the corresponding green pulses 410 of the green emission due to the influence of the low-intensity emissions 416 of the red emission 422 and/or the low-intensity emissions 420 of the blue emission 424. Thus, the green color point 504 (see FIGS. 5A and 5B) of the illumination beam 102 can be shifted, providing the ability to adjust the color gamut of the illumination beam 102 as described above. Further, the green pulses 402 of the illumination beam 102 may have higher intensity than the corresponding pulses 410 of the green emission 408 due to added optical power from the overlapping emissions 416, 420 of the red and/or blue emissions 422, 424, respectively. Accordingly, the green channel of the illumination beam 102 may have increased brightness. The same applies to the red and blue channels. For example, the red pulses 404 in the illumination beam 102 may be of a somewhat different shade or hue of red than are the corresponding pulses 414 of the red emission 422 due to the influence of the low-intensity emissions 412 of the green emission 408 and/or the low-intensity emissions 420 of the blue emission 424. Thus, the red color point 506 (see FIGS. 5A and 5B) can be shifted to adjust the color gamut of the illumination beam 102. Further, the intensity of the red pulses 404 of the illumination beam 102 may be higher than the intensity of the corresponding pulses 414 of the red emission 422 due to added optical power from the overlapping emissions 412, 420 of the green and/or blue emissions 408, 424, respectively. Thus, the red channel of the illumination beam 102 may have increased brightness. Similarly, the blue pulse 406 in the illumination beam 102 may be of a somewhat different shade or hue of blue than is the corresponding pulse 418 of the blue emission 424 due to the influence of the low-intensity emission 412 of the green emission 408 and/or the low-intensity emission 416 of the red emission 422. Thus, the blue color point 508 (see FIGS. 5A and 5B) can be shifted to adjust the color gamut of the illumination beam 102. Further, the intensity of the blue pulse 406 of the illumination beam 102 may be higher than the intensity of the corresponding pulse 418 of the blue emission 424 due to added optical power from the overlapping emissions 412, 416 of the green and/or red emissions 408, 422, respectively. Accordingly, the blue channel of the illumination beam 102 may have increased brightness. Thus, as described above, through control of the individual color channels, the color gamut of the illumination beam can be adjusted and desaturated, while the overall brightness of the illumination beam can be increased.

In some examples, a technique referred to as color overlap can be used to increase the brightness of the illumination beam while also desaturating the color gamut. An example of emission spectra for the laser light source 110 controlled to employ color overlap, specifically yellow overlap, is illustrated in FIG. 4B. In this example, the illumination beam 102, during the sequence period, Sp, comprises two yellow pulses 426 in addition to the green pulses 402, the red pulses 404, and the blue pulse 406. In some examples, to produce the yellow pulses 426, the green emission 408 includes two corresponding additional high-intensity pulses 428 (e.g., produced at the intensity level G1) that overlap in time with portions of the red pulses 414, as shown in FIG. 4B. Accordingly, in some instances, the red pulses 414 in the red emission 422 of FIG. 4B may have longer durations than do the red pulses 414 in the red emission 422 of FIG. 4A, to allow time to produce the yellow pulses 426. In some instances, the durations of the green pulses 410 and the blue pulse 418 in the color overlap example of FIG. 4B may be shorter than their counterparts in the example of FIG. 4A, to allow time within the same-duration sequence period to accommodate the longer red pulses 414 to produce the yellow pulses 426.

In other examples, a different color of color overlap can be employed. For example, some laser light sources 110 may use cyan overlap in which the illumination beam 102 includes one or more cyan pulses produced by overlapping one or more green and blue pulses from the green and blue emissions 408, 424, respectively. In another example, the laser light source 110 can be configured to use magenta overlap in which the illumination beam 102 includes one or more pulses of magenta light produced via one or more overlapping pulses from the red and blue emissions 422, 424, respectively. According to some examples, yellow color overlap may be used in applications where maximum brightness is desired, as the additional green and red emissions add to the overall brightness of the illumination beam 102. Cyan and/or magenta color overlap, for example, may be used for color purity since additional blue emission may not add significant brightness based on a typical human eye response curve.

In the examples of FIGS. 4A and 4B, the low-intensity green, red, and blue emissions 412, 416, and 420, respectively, are illustrated as uniform over their respective portions of the sequence period. Thus, the low-intensity emission 412 from the green laser has the same intensity level, G2, when overlapping with the red pulses 414 of the red emission 422 as when overlapping with the blue pulse 418 of the blue emission 424. However, in other examples, the low-intensity emissions of any one or more of the green, red, and/or blue lasers may have varying average (or effective) intensity levels.

For example, referring to FIG. 4C, the laser controller 120 can be configured to control the green laser to produce the green emission 408 having different low-intensity emissions 430, 432 with different average intensity levels G2, G3, respectively. Thus, the emissions 430 of the green emission 408 that overlap in time with the red pulses 414 of the red emission 422 may have an average intensity level G2, whereas the emission 432 of the green emission 408 that overlaps in time with the pulse 418 of the blue emission 424 may have an average intensity level G3. Similarly, the laser controller 120 can be configured to control the red laser to produce the red emission 422 having different low-intensity emissions 434, 436 with different average intensity levels R2, R3, respectively. Thus, the emissions 434 of the red emission 422 that overlap in time with the green pulses 412 of the green emission 408 may have an average intensity level R2, whereas the emission 436 of the red emission 422 that overlaps in time with the pulse 418 of the blue emission 424 may have an average intensity level R3. Further, the laser controller 120 can be configured to control the blue laser to produce the blue emission 424 having different low-intensity emissions 438, 440 with different intensity levels B2, B3, respectively. Thus, the emissions 438 of the blue emission 424 that overlap in time with pulses 410 of the green emission 408 may have an average intensity level B2, whereas the emissions 440 of the blue emission 424 that overlap in time with the red pulses 414 of the red emission 422 may have an average intensity level B3.

In the example illustrated in FIG. 4C, G3 is higher than G2, R2 is higher than R3, and B3 is higher than B2. However, in other examples, the opposite in any case may be true, such that G2 may be higher than G3, R3 may be higher than R2, and/or B2 may be higher than B3. The various intensity levels may be selected based on the amount of additional color (from other lasers) to be added to a given channel to achieve a desired color point for that channel and a desired overall white point. For example, adding more green to the blue channel may shift the blue color point 508 further towards cyan. As described above, in some examples, the laser controller 120 can be configured to vary any of the intensity levels G1, G2, G3, R1, R2, R3, B1, B2, and/or B3 to achieve, when combined, a desired color gamut and white point for the illumination beam 102. In some examples, G2, G3, R2, R3, B2, and B3 are all averaged/effective non-zero intensity levels. However, in other examples, one or more of G2, G3, R2, R3, B2, and/or B3 may be zero. The intensity levels G1, R1, and B1 are higher than any of G2, G3, R2, R3, B2, and B3.

As described above, in some examples, the different intensity levels (G1, G2, G3, R1, R2, R3, B1, B2, B3, etc.) can be achieved by varying the drive current for the individual lasers to change the optical power of the respective emissions. In such examples, the lasers may emit at the particular intensity levels. In such cases, the actual emission intensity and the average/effective intensity for a given time duration (e.g., the time period corresponding to the green low-intensity emission 412) may be substantially the same. In other examples, the different average/effective intensity levels can be controlled by using pulse width modulation to achieve specified average optical power over the durations of respective pulses/segments of the various emissions. An example is illustrated in FIG. 4D.

FIG. 4D illustrates an example of the green emission 408 with the effective output intensity of the low intensity emissions 412 being achieved using pulse width modulation control. As illustrated, the low intensity emissions 412 may each comprise a series of individual pulses 442. Thus, during the time periods corresponding to the low intensity emissions 412, the green laser can be turned on (emitting the pulses 442) and off, with the individual durations and number of pulses 442 being selected (e.g., specified by the control signal) to achieve the desired effective/average intensity level (e.g., G2 or G3 illustrated in FIGS. 4A, 4B and 4C). In the illustrated example of FIG. 4D, the green laser can be controlled to emit the pulses 442 with the same actual intensity/optical power (e.g., G1) as the green pulses 410. This configuration may simplify implementation in that the same drive current can be used to produce both the high-intensity emissions (green pulses 410) and the low-intensity emissions (pulses 442 that average, with the periods of zero emission, to produce the low-intensity portions 412). However, in other examples, the pulses 442 can be emitted at power levels that are higher or lower than the power level at which the green pulses 410 are emitted. In either arrangement, the power level of the pulses 442 can be selected such that the corresponding drive current for the green laser is well above the lasing threshold and in a region of stable operation of the green laser. Further, while the green pulses 410 are shown implemented as continuous periods of emission by the green laser, in other examples, the green pulses 410 can similarly be produced using pulse width modulation. For example, during time periods corresponding to the green pulses 410, the green laser can be pulsed at a certain rate and/or with a certain drive current so as to produce an emission with the effective/average intensity level G1, and during time periods corresponding to the low-intensity portions 412, the green laser can be pulsed at a different rate and/or with a different drive current so as to produce an emission with the effective/average intensity level G2 or G3. While FIG. 4D illustrates an example for the green emission 408, a similar approach can be applied for the red and/or blue emissions 422, 424.

Referring again to FIGS. 4A-C, as shown, the output intensities of the green, red, and blue pulses 402, 404, 406, respectively, in the illumination beam 102 may be different, and the durations (or percentages of the sequence period occupied by) the green, red, and blue color sequences may be different. As described above, the intensities and the durations of the different color contributions (e.g., the pulses 402, 404, 406, and optionally 426) in the illumination beam 102 can be selected to produce the illumination beam 102 having a desired color gamut and white point.

FIGS. 5A and 5B are chromaticity plots (e.g., according to the CIE 1931 color spaces published in 1931 by the International Commission on Illumination, which describe the relationship between the visible spectrum and the visual sensation of specific colors by human color vision) illustrating a color spectrum 502 for the laser light source 110 according to certain examples. Referring to FIG. 5A, in this example, the illumination beam 102 comprises a green color point 504a (corresponding to the green pulses 402), a red color point 506a (corresponding to the red pulses 404), and a blue color point 508a (corresponding to the blue pulse 406). The illumination beam 102 has a white point 510a that is based on the color points 504a, 506a, 508a (e.g., the x and y color coordinates representing each color point) and the respective durations of the pulses 402, 404, 406, or more specifically, the percentages of the duration of the sequence period, Sp, allocated to each of the green, red, and blue pulses 402, 404, 406, respectively. Further, in this example, the illumination beam 102 has a color gamut 512a described by the color space enclosed by a triangle with the green, red, and blue color points 504a, 506a, 508a at its vertices, as illustrated in FIG. 5A.

The shades or hues of the individual color points 504a, 506a, 508a, or their x-y coordinates, may be determined at least in part by characteristics of the corresponding green, red, and blue lasers (e.g., the particular emission wavelengths) and by the contributions of the other colors added into each respective channel, as described above. For example, as described above, the color coordinates of the green pulses 402 in the illumination beam (and thus of the green color point 504a) are affected/altered by the amount of red and/or blue light (e.g., portions 416, 420, 434, and/or 438) added to the green channel. The same applies to the red and blue channels. Accordingly, the laser controller 120 can be configured to adjust any one or more of the color points 504a, 506a, 508a, and thus the color gamut 512a, by altering the intensities of the light from other channels that is added to any given color channel. For example, the green color point 504a can be altered by altering the overlapping red and/or blue intensity levels R2 (or R3) and/or B2 (or B3). Similarly, the laser controller can alter the red color point 506a by changing the overlapping green and/or blue intensity levels G2 (or G3) and/or B2 (or B3), and alter the blue color point 508a by changing the overlapping green and/or red intensity levels G2 (or G3) and/or R2 (or R3).

An example is illustrated in FIG. 5B. In this example, illumination beam 102 has a green color point 504b, a red color point 506b, and a blue color point 508b. As may be seen by comparing FIGS. 5A and 5B, the color coordinates of the green, red, and blue color points have been changed, which as described above, can be achieved by altering, in any one or more of the color sequences, the contributions of light of other colors. For example, the red color point 506b is moved more towards the yellow (relative to the red color point 506a) by adding more green light to the red color sequence. Similarly, the green color point 504b is shifted “downwards” relative to the color point 504a, by adding higher amounts of red and blue light to the green color sequence. As a result, in this example, the color gamut 512b is reduced and desaturated relative to the color gamut 512a illustrated in FIG. 5A. As described above, desaturating the color gamut advantageously can make displayed images appear more natural in some instances. Further, this alteration of the color points and the color gamut can be achieved while maintaining a relatively constant white point. For example, the white point 510b in the example of FIG. 5B has essentially the same (or very similar) color coordinates as the white point 510a in the example of FIG. 5A. In addition, as described above, the desaturation of the color gamut 512b may be achieved while also advantageously increasing the brightness of the illumination beam through the added optical power from other lasers for a given color channel. In addition, by driving multiple lasers of different colors during the same time period, the resulting wavelength diversity can decrease the coherence of the output beam, which can reduce or improve laser speckle.

According to certain examples, the laser controller 120 alters the pulse width modulation control signals applied to the individual lasers 112 of the laser light source 110 to achieve a combination of optical power contributions from the various colors for each color sequence/channel. In some examples, the optical power contributions for each color can be expressed as a percentage of the total optical power for a particular channel, which in turn can be expressed as a total duty cycle (e.g., emitting time) for individual lasers as a percentage of the sequence period. Table 1 below provides an example.

TABLE 1

| | Red Laser | Green Laser | Blue Laser |
|---|---|---|---|
| Red Channel | 35% | 6% | 0% |
| Green Channel | 17% | 45% | 4% |
| Blue Channel | 4% | 3% | 25% |
| Total Duty Cycle | 55% | 44% | 29% |
| Per Laser | | | |

It will be appreciated that Table 1 provides one example; however, numerous variations are possible depending on the particular color gamut desired for any given application. Through the use of pulse width modulation control of a combination of the red, green and/or blue lasers 112 for each of the red, green and blue channel, desired desaturation of the color gamut can be achieved while also maintaining a balanced/desired white color point.

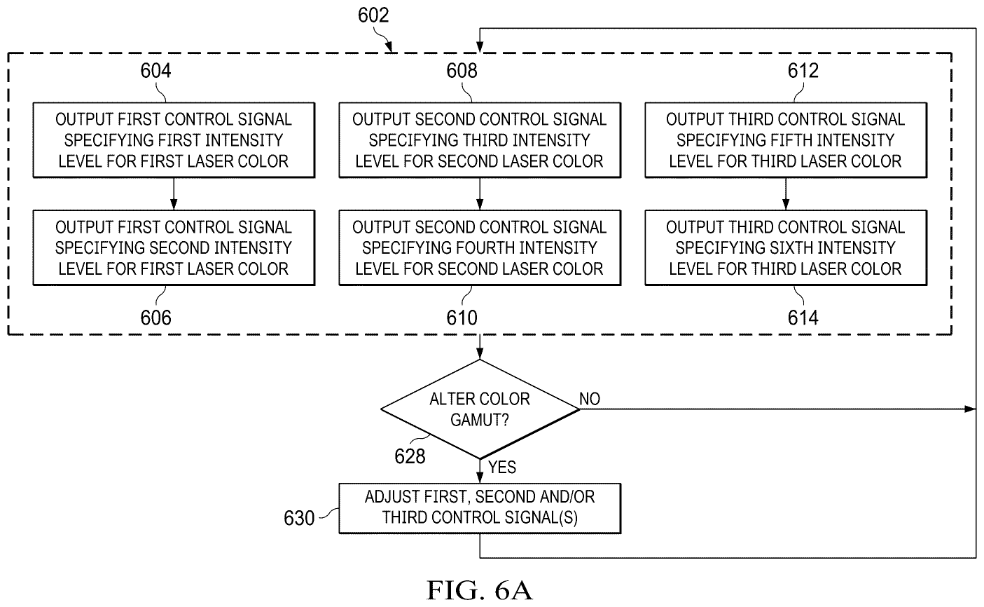

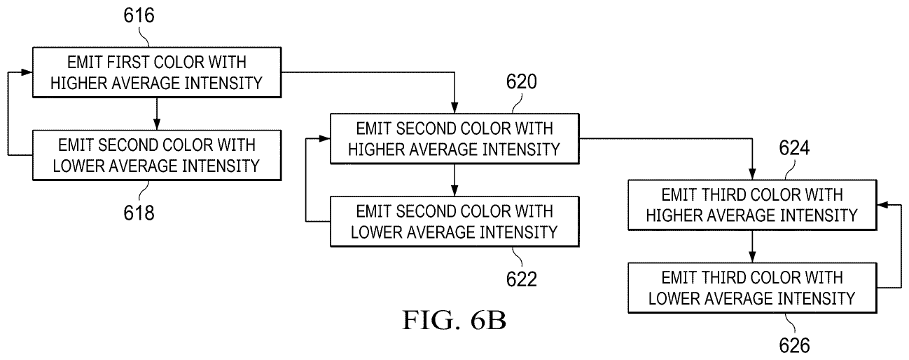

Referring to FIG. 6A, there is illustrated a flow diagram of a method of controlling a multi-color laser light source, according to an example.

Operation 602 includes outputting, by the laser controller 120, control signals for the various color channels of the laser light source 110. In the example illustrated in FIG. 6A, the laser light source includes three color channels; however, as described above, in other examples, there may be more than or fewer than three color channels.

In some examples, at operation 604, the laser controller 120 may output a first control signal specifying a first average non-zero intensity level at which a first laser is instructed to produce first laser light having a first color. As described above, operation 604 may be performed during a first time period, which may correspond to a first portion/segment of the sequence period, Sp. For example, for the green laser, operation 604 may include providing the first control signal to instruct the green laser to emit the pulses 410 of the green emission 408.

At operation 606, the laser controller 120 may output the first control signal specifying a second average non-zero intensity level at which the first laser is instructed to produce the first laser light having the first color. As described above, the second average non-zero intensity level may be lower than the first average non-zero intensity level. For example, for the green laser, operation 606 may include providing the first control signal to instruct the green laser to emit the low-intensity emissions 412 of the green emission 408. As described above, operation 606 may be performed during a second time period, which in some examples, may correspond to a first remainder of the sequence period, Sp.

At operation 608, the laser controller 120 may output a second control signal specifying a third average non-zero intensity level at which a second laser is instructed to produce second laser light having a second color. The second color is different from the first color. For example, for the red laser, operation 608 may include providing the second control signal to instruct the red laser to emit the low-intensity emissions 416. Accordingly, and as described above, operation 608 may be performed during at least a portion of the first time period and thus at least partially concurrently with operation 604.

At operation 610, the laser controller may output the second control signal specifying a fourth average non-zero intensity level at which the second laser is instructed to produce the second laser light having the second color. For example, for the red laser, operation 610 may include providing the second control signal to instruct the red laser to emit the pulses 414 of the red emission 422. Accordingly, the fourth average non-zero intensity level may be higher than the second and third average non-zero intensity levels (e.g., R1 may be higher than R2 and G2, as described above). Operation 610 may be performed during at least a portion of the second time period, and thus at least partially concurrently with operation 606.

As described above, in some examples, operation 602 additionally includes emitting a control signal for a third color channel. Accordingly, at operation 612, the laser controller 120 may output a third control signal specifying a fifth average non-zero intensity level at which a third laser is instructed to produce third light having a third color. The third color is different from the first and second colors. For example, for the blue laser, operation 612 may include providing the third control signal to instruct the blue laser to emit the pulse 418 of the blue emission 424. Accordingly, operation 612 may be performed during a third time period that is at least partially overlapping in time with the second time period. As such, operation 612 may be performed at least partially concurrently with operations 606 and/or 608.

At operation 614, the laser controller 120 may output the third control signal specifying a sixth average non-zero intensity level at which the third laser is instructed to produce the third laser light. For example, for the blue laser, operation 614 may include providing the third control signal to instruct the blue laser to emit low-intensity emissions 420. Accordingly, the fifth average non-zero intensity level may higher than the sixth average non-zero intensity level (e.g., B1 is higher than B2). In some examples, operation 614 is performed during a fourth time period that is at least partially overlapping in time with the first time period. Accordingly, operation 614 may be performed at least partially concurrently with operations 604, 606, 608, and/or 610.

FIG. 6B illustrates a flow diagram of a method of operating a multi-color light source (e.g., the light source 110) according to operation 602 of FIG. 6A.

For example, operation 616 includes emitting (e.g., with a first laser) first laser light in a first spectral range (e.g., a first color) with a first average non-zero intensity level, and operation 618 includes emitting (e.g., with the first laser) the first laser light with at least a second average non-zero intensity level. In one example, the first average non-zero intensity level is higher than the second average non-zero intensity level. Thus, operation 616 may include emitting the first color with relatively higher average intensity, whereas operation 618 may include emitting the second color with relatively lower average intensity. Operation 616 may be performed for a first portion of a time period, and operation 618 may be performed for a second portion of the time period. Thus, in some examples, operation 616 may be performed in response to operation 604, and operation 618 may be performed in response to operation 606.

In one example, operation 620 includes emitting (e.g., with a second laser) second laser light in a second spectral range (e.g., a second color) with a third average non-zero intensity level, and operation 622 includes emitting (e.g., with the second laser) the second laser light with at least a fourth average non-zero intensity level. In one example, the third average non-zero intensity level is higher than the second and fourth average non-zero intensity levels. Thus, operation 620 may include emitting the second color with relatively higher average intensity, whereas operation 622 may include emitting the second color with relatively lower average intensity. In some examples, operation 620 is performed for a third portion of the time period, and operation 622 is performed for a fourth portion of the time period. The third portion of the time period may at least partially overlap with the second portion of the time period. Thus, in some examples, operation 620 may be performed in response to operation 610, and operation 622 may be performed in response to operation 608.

In one example, operation 624 includes emitting (e.g., with a third laser), third laser light in a third spectral range (e.g., a third color) with a fifth average non-zero intensity level, and operation 626 includes emitting (e.g., with the third laser) the third laser light with at least a sixth average non-zero intensity level. In one example, the fifth average non-zero intensity level is higher than the second, fourth, and sixth average non-zero intensity levels. Thus, operation 624 may include emitting the third color with relatively higher average intensity, whereas operation 626 may include emitting the third color with relatively lower average intensity. Operation 624 may be performed for a fifth portion of the time period that at least partially overlaps with the second and fourth portions of the time period, and operation 626 may be performed for a sixth portion of the time period. Thus, in some examples, operation 624 may be performed in response to operation 612, and operation 626 may be performed in response to operation 614.

According to certain examples, the laser light source 110, for individual color channels, can alternate between emitting the respective colors at the relatively higher average intensity levels and emitting the respective colors at the relatively lower average intensity levels, as shown in FIG. 6B. The values of the intensity levels can be altered by altering the control signals supplied by the laser controller 120, as described above. Thus, any of operations 616-626 may be performed at different average intensity levels at different times, as specified by the control signals from the laser controller 120.

Returning to FIG. 6A, as described above, in some examples, the laser controller 120 may receive an instruction to alter the color gamut of the illumination beam 102. For example, the laser controller may receive a sensor signal from the sensor 300 indicating that the color gamut of the illumination beam should be changed, or otherwise receive an instruction or information indicating that the color gamut of the illumination beam 102 is to be changed. Accordingly, the method illustrated in FIG. 6A may include operation 628 of determining whether the color gamut of the illumination beam 102 is to be altered. This determination may be made in response to, or based on, the signal from the sensor 300 or other information/feedback received by the laser controller 120.

If the color gamut is to be altered, the laser controller 120 may adjust, at operation 630, any one or more of the first, second, and/or third control signals to instruct the laser light source 110 to alter the respective emissions for any one or more color channels. For example, operation 630 may include adjusting any one or more of the first, second, and/or third control signals to vary any of the intensity levels G1, G2, G3, R1, R2, R3, B1, B2, and/or B3 to achieve, when combined, a desired color gamut at a particular white point for the illumination beam 102, as described above. Operation 602 may then be performed by outputting the adjusted control signals.

### Conclusion

Thus, examples described herein provide a light projection system 100 and control methodology that may provide higher image quality (through reduced laser speckle) and brightness improvement, while also offering dynamically variable and controllable color desaturation.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Elements that are “optically coupled” have an optical path between them. For example, element A and element B are optically coupled if light may travel from element A to element B and/or light may travel from element B to element A. Being optically coupled does not require light to be actively propagating between the elements. Optically coupled elements are in an arrangement where light, if present, is capable of propagating from element A to element B or from element B to element A. Additionally, elements that are optically coupled may have additional elements, for example lenses, mirrors, prisms, light tunnels, or other optical elements, in the light path between them.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within a range of that parameter, such as +/−10 percent of that parameter or +/−5 percent of that parameter.

The description above discloses, among other things, various example systems, methods, apparatus, and articles of manufacture including, among other components, firmware and/or software executed on hardware. It is understood that such examples are merely illustrative and should not be considered as limiting. For example, it is contemplated that any or all of the firmware, hardware, and/or software aspects or components can be embodied exclusively in hardware, exclusively in software, exclusively in firmware, or in any combination of hardware, software, and/or firmware. Accordingly, the examples provided are not the only ways to implement such systems, methods, apparatus, and/or articles of manufacture.

The specification is presented largely in terms of illustrative environments, systems, procedures, steps, logic blocks, processing, and other symbolic representations that directly or indirectly resemble the operations of data processing devices coupled to networks. These process descriptions and representations are typically used by those skilled in the art to most effectively convey the substance of their work to others skilled in the art. Numerous specific details are set forth to provide a thorough understanding of the present disclosure. However, it is understood to those skilled in the art that certain examples described herein can be practiced without certain, specific details. In other instances, well known methods, procedures, components, and circuitry have not been described in detail to avoid unnecessarily obscuring aspects of the examples. Accordingly, the scope of the present disclosure is defined by the appended claims rather than the foregoing description of examples.

When any of the appended claims are read to cover a purely software and/or firmware implementation, at least one of the elements in at least one example is hereby expressly defined to include a tangible, non-transitory medium such as a memory, DVD, CD, Blu-ray, and so on, storing the software and/or firmware.

### Further Examples

The following examples pertain to further arrangements and/or implementations, from which numerous permutations and configurations will be apparent.

Example 1 is laser controller configured to: during a first time period, output a first control signal specifying a first average non-zero intensity level at which a first laser is instructed to produce first laser light having a first color; during a second time period, output the first control signal specifying a second average non-zero intensity level at which the first laser is instructed to produce the first laser light having the first color, the second average non-zero intensity level being lower than the first average non-zero intensity level; during at least a portion of the first time period, output a second control signal specifying a third average non-zero intensity level at which a second laser is instructed to produce second laser light having a second color; and during at least a portion of the second time period, output the second control signal specifying a fourth average non-zero intensity level at which the second laser is instructed to produce the second laser light having the second color, the fourth average non-zero intensity level being higher than the second and third average non-zero intensity levels and the second color being different than the first color.

Example 2 includes the laser controller of Example 1, further configured to: during a third time period, output a third control signal specifying a fifth average non-zero intensity level at which a third laser is instructed to produce third light having a third color, the third time period at least partially overlapping in time with the second time period; and during a fourth time period, output the third control signal specifying a sixth average non-zero intensity level at which the third laser is instructed to produce the third laser light, fifth average non-zero intensity level being higher than the sixth average non-zero intensity level, and the fourth time period at least partially overlapping in time with the first time period.

Example 3 includes the laser controller of Example 2, wherein the first, second, and third control signals are pulse width modulation signals, and wherein the pulse width modulation signals are configured to specify respective pulse duty cycles, during the first, second, and fourth time periods, to produce the second, third, and sixth average non-zero intensity levels.

Example 4 includes the laser controller of one of Examples 2 or 3, wherein the laser controller is configured to control the durations of the first, second, third, and fourth time periods, and/or the first, second, third, fourth, fifth, and sixth signal levels to desaturate a color gamut of a laser beam comprising the first, second, and third laser light.

Example 5 includes the laser controller of any one of Examples 1-4, wherein a sum of a duration of the first time period and a duration of the second time period is equal to a duration of a sequence period for display of a frame of image data.

Example 6 is a light projection system comprising: a laser light source configured to emit a laser beam, the laser light source including a first laser configured to emit first laser light in a first spectral range and a second laser configured to emit second laser light in a second spectral range different from the first spectral range; a laser controller coupled to the laser light source and configurable to control a color gamut of the laser beam by controlling respective intensities of the first laser light emitted by the first laser and the second laser light emitted by the second laser, the laser controller configurable to (i) produce a first control signal to operate the first laser to emit the first laser light with a first average non-zero intensity level for a first time period and with a second average non-zero intensity level for a second time period, the first average non-zero intensity level being higher than the second average non-zero intensity level, and (ii) produce a second control signal to operate the second laser to emit the second laser light with a third average non-zero intensity level for at least a portion of the first time period and with a fourth average non-zero intensity level for at least a portion of the second time period, the fourth average non-zero intensity level being higher than the second and third average non-zero intensity levels; and a spatial light modulator optically coupled to the laser light source and configured to project an image based on the laser beam.

Example 7 includes the light projection system of Example 6, wherein the laser light source further includes a third laser configured to emit third laser light in a third spectral range different from the first and second spectral ranges; wherein the laser controller is further configurable to produce a third control signal to operate the third laser to emit the third laser light with a fifth average non-zero intensity level for a third time period and with a sixth average non-zero intensity level for a fourth time period, the fifth average non-zero intensity level being higher than the sixth average non-zero intensity level; wherein the third time period at least partially overlaps in time with the second time period; and wherein the fourth time period at least partially overlaps in time with the first time period.

Example 8 includes the light projection system of Example 7, wherein the first laser is a green laser, the second laser is a red laser, and the third laser is a blue laser.

Example 9 includes the light projection system of any one of Examples 6-8, wherein a sum of a duration of the first time period and a duration the second time period is equal to a duration of a sequence period for display of the image.

Example 10 includes the light projection system of Examples 9, wherein the duration of the sequence period is below a critical flicker fusion threshold of the laser light source.

Example 11 includes the light projection system of any one of Examples 6-10, further comprising a display device configured to display the image projected by the light projection system.

Example 12 includes the light projection system of Example 11, wherein the laser controller is further configurable to alter at least one of the first or second control signals based on a signal from the display device to adjust the color gamut of the laser beam.

Example 13 includes the light projection system of any one of Examples 6-12, further comprising at least one sensor coupled to the laser controller and the at least one sensor configured produce a sensor signal indicative of at least one parameter of the color gamut of the laser beam, wherein the laser controller is configurable to alter, based on the sensor signal, at least one of the first or second control signals to adjust the color gamut of the laser beam.

Example 14 includes the light projection system of any one of Examples 6-13, further comprising illumination optics optically coupled between the laser light source and the spatial light modulator, the illumination optics comprising a light tunnel and at least one diffuser.

Example 15 includes the light projection system of Example 14, wherein the at least one diffuser comprises a static diffuser positioned between the laser light source and the light tunnel, the static diffuser configured to expand a spot size of the laser beam at the light tunnel.

Example 16 includes the light projection system of Example 15, wherein the at least one diffuser further comprises a movable diffuser optically coupled between the static diffuser and the light tunnel, the movable diffuser configured to angularly expand the laser beam within a pupil of the light projection system.

Example 17 includes the light projection system of Example 16, wherein the static diffuser is a first static diffuser, and wherein the at least one diffuser further comprises a second static diffuser optically coupled between the light tunnel and the spatial light modulator, the second static diffuser configured to homogenize the laser beam within the pupil of the light projection system.

Example 18 includes the light projection system of any one of Examples 6-17, further comprising a modulation controller coupled to the spatial light modulator.

Example 19 is a method of operating a multi-color laser light source, the method comprising: emitting, with a first laser of the multi-color laser light source, first laser light in a first spectral range with a first average non-zero intensity level for a first portion of a time period and with at least a second average non-zero intensity level for a second portion of the time period, wherein the first average non-zero intensity level is higher than the second average non-zero intensity level; emitting, with a second laser of the multi-color laser light source, second laser light in a second spectral range with a third average non-zero intensity level for a third portion of the time period and with at least a fourth average non-zero intensity level for a fourth portion of the time period, wherein the third average non-zero intensity level is higher than the second and fourth average non-zero intensity levels, wherein the third portion of the time period at least partially overlaps with the second portion of the time period; and emitting, with a third laser of the multi-color laser light source, third laser light in a third spectral range with a fifth average non-zero intensity level for a fifth portion of the time period and with at least a sixth average non-zero intensity level for a sixth portion of the time period, wherein the fifth average non-zero intensity level is higher than the second, fourth, and sixth average non-zero intensity levels, wherein the fifth portion of the time period at least partially overlaps with the second and fourth portions of the time period.

Example 20 includes the method of Example 19, wherein emitting the second laser light comprises: emitting the second laser light with the fourth average non-zero intensity level while emitting the first laser light with the first intensity level; and emitting the second laser light with a seventh intensity level higher than the fourth intensity level and lower than third intensity level while emitting the third laser light with the fifth intensity level.

Example 21 includes the method of one of Examples 19 or 20, wherein a duration of the time period is below a critical flicker fusion threshold of the multi-color laser light source.

Example 22 includes the method of any one of Examples 19-21, wherein emitting the first laser light comprises emitting green laser light; wherein emitting the second laser light comprises emitting red laser light; and wherein emitting the third laser light comprises emitting blue laser light.

Example 23 includes the method of any one of Examples 16-22, wherein a sum of durations of the first and second portions of the time period is equal to a duration of the time period, wherein a sum of durations of the third and fourth portions of the time period is equal to the duration of the time period, and wherein a sum of durations of the fifth and sixth portions of the time period is equal to the duration of the time period.

Example 24 is a method of driving a multi-color laser light source, the method comprising: controlling a first laser of the multi-color laser light source to emit first laser light in a first spectral range with a first average non-zero intensity level for a first portion of a time period and with at least a second average non-zero intensity level for a second portion of the time period, wherein the first average non-zero intensity level is higher than the second average non-zero intensity level, and wherein a sum of durations of the first and second portions of the time period is equal to a duration of the time period; controlling a second laser of the multi-color laser light source to emit second laser light in a second spectral range with a third average non-zero intensity level for a third portion of the time period and with at least a fourth average non-zero intensity level for a fourth portion of the time period, wherein the third average non-zero intensity level is higher than the second and fourth average non-zero intensity levels, wherein the third portion of the time period at least partially overlaps with the second portion of the time period, and wherein a sum of durations of the third and fourth portions of the time period is equal to the duration of the time period; controlling a third laser of the multi-color laser light source to emit third laser light in a third spectral range with a fifth average non-zero intensity level for a fifth portion of the time period and with at least a sixth average non-zero intensity level for a sixth portion of the time period, wherein the fifth average non-zero intensity level is higher than the second, fourth, and sixth average non-zero intensity levels, wherein the fifth portion of the time period at least partially overlaps with the second and fourth portions of the time period, and wherein a sum of durations of the fifth and sixth portions of the timer period is equal to the duration of the time period; and selecting the second, fourth, and sixth intensity levels to desaturate a color gamut of a laser beam comprising the first, second, and third laser light.

Example 25 is a laser controller configured to: produce a first control signal to control an intensity of first laser light of a first color emitted by a first laser of a multi-color laser light source, the first control signal operable to adjust the intensity of the first laser light between at least high and low average non-zero intensity levels during a sequence period; and produce a second control signal to control an intensity of second laser light of a second color emitted by a second laser of the multi-color laser light source, the second control signal operable to adjust the intensity of the second laser light between at least high and low average non-zero intensity levels during the sequence period; wherein, during the sequence period, an occurrence of the low average non-zero intensity level emitted by the first laser at least partially overlaps in time with an occurrence of the high average non-zero intensity level emitted by the second laser; wherein, during the sequence period, an occurrence of the low average non-zero intensity level emitted by the second laser at least partially overlaps in time with an occurrence of the high average non-zero intensity level emitted by the first laser; and wherein the first and second colors are different.

Example 26 includes the laser controller of Example 25, further configured to produce a third control signal to control an intensity of third laser light of a third color emitted by a third laser of the multi-color laser light source, the third control signal operable to adjust the intensity of the third laser light between at least high and low average non-zero intensity levels during the sequence period, wherein, during the sequence period, an occurrence of the high average non-zero intensity level emitted by the third laser at least partially overlaps in time with an occurrence of the low average non-zero intensity level emitted by the first laser and/or an occurrence of the low average non-zero intensity level emitted by the second laser.

Example 27 includes the laser controller of Example 26, wherein the first, second, and third control signals are pulse width modulation signals.

Example 28 includes the laser controller of one of Examples 26 or 27, wherein the first, second, and third colors include red, green, and blue.

Example 29 includes the laser controller of any one of Examples 26-28, wherein the first control signal is further operable to adjust the intensity of the first laser light to an intermediate intensity level that is between the high and low average non-zero intensity levels emitted by the first laser; wherein the second control signal is further operable to adjust the intensity of the second laser light to an intermediate intensity level that is between the high and low average non-zero intensity levels emitted by the second laser; and/or wherein the third control signal is further operable to adjust the intensity of the third laser light to an intermediate intensity level that is between the high and low average non-zero intensity levels emitted by the third laser.

Example 30 includes the laser controller of Example 29, wherein, during the sequence period, an occurrence of the low average non-zero intensity level emitted by any one of the first, second, or third lasers at least partially overlaps in time with an occurrence of the intermediate intensity level emitted by any one or both of the other two of the of the first, second, or third lasers.

Example 31 includes the laser controller of any one of Examples 25-30, wherein the first control signal is configured to adjust a duration of the occurrence of the high average non-zero intensity level emitted by the first laser, and the second control signal is configured to adjust a duration of the occurrence of the high average non-zero intensity level emitted by the second laser.

Example 32 is a laser controller configured to drive a plurality of lasers of a multi-color laser light source simultaneously during each color sequence within a display frame, wherein the plurality of lasers emit light of different colors.

Example 33 is a laser controller configured to drive a multi-color laser light source such that, during a first color sequence in which a first laser is controlled to emit light of a first color with high optical power, a second laser is controlled to emit light of a second color with low average/effective optical power, and during a second color sequence in which the second laser is controlled to emit light of the second color with high optical power, the first laser is controlled to emit light of the first color with low average/effective optical power.

Example 34 includes the laser controller of Example 33, wherein the laser controller is further configured to drive the multi-color laser light source such that, during the first and second color sequences, a third laser is controlled to emit light of a third color with low average/effective optical power, and during a third color sequence in which the third laser is controlled to emit light of the third color with high optical power, the first and second lasers are controlled to emit light of the first and second colors, respectively, with low average/effective optical power.

Example 25 includes the laser controller of Example 34, wherein the first, second, and third colors are green, red, and blue, respectively.

Example 26 is a method of driving a multi-color laser light source in which multiple lasers of different colors are operated simultaneously to improve brightness and reduce laser speckle.

1. A laser controller configurable to:
during a first time period, output a first control signal specifying a first average non-zero intensity level at which a first laser is instructed to produce first laser light having a first color;
during a second time period, output the first control signal specifying a second average non-zero intensity level at which the first laser is instructed to produce the first laser light having the first color, the second average non-zero intensity level being lower than the first average non-zero intensity level;
during at least a portion of the first time period, output a second control signal specifying a third average non-zero intensity level at which a second laser is instructed to produce second laser light having a second color; and
during at least a portion of the second time period, output the second control signal specifying a fourth average non-zero intensity level at which the second laser is instructed to produce the second laser light having the second color, the fourth average non-zero intensity level being higher than the second and third average non-zero intensity levels and the second color being different than the first color.

2. The laser controller of claim 1, further configured to:
during a third time period, output a third control signal specifying a fifth average non-zero intensity level at which a third laser is instructed to produce third light having a third color, the third time period at least partially overlapping in time with the second time period; and
during a fourth time period, output the third control signal specifying a sixth average non-zero intensity level at which the third laser is instructed to produce the third laser light, the fifth average non-zero intensity level being higher than the sixth average non-zero intensity level, and the fourth time period at least partially overlapping in time with the first time period.

3. The laser controller of claim 2, wherein the first, second, and third control signals are pulse width modulation signals; and
wherein the pulse width modulation signals specify respective pulse duty cycles, during the first, second, and fourth time periods, to produce the second, third, and sixth average non-zero intensity levels.

4. The laser controller of claim 2, wherein the laser controller is configured to control the durations of the first, second, third, and fourth time periods, and/or the first, second, third, fourth, fifth, and sixth signal levels to desaturate a color gamut of a laser beam comprising the first, second, and third laser light.

5. The laser controller of claim 1, wherein a sum of a duration of the first time period and a duration of the second time period is equal to a duration of a sequence period for display of a frame of image data.

6. A light projection system comprising:
a laser light source configured to emit a laser beam, the laser light source including a first laser configured to emit first laser light in a first spectral range and a second laser configured to emit second laser light in a second spectral range different from the first spectral range;
a laser controller coupled to the laser light source and configurable to control a color gamut of the laser beam by controlling respective intensities of the first laser light emitted by the first laser and the second laser light emitted by the second laser, the laser controller configurable to
(i) produce a first control signal to operate the first laser to emit the first laser light with a first non-zero average intensity level for a first time period and with a second average non-zero intensity level for a second time period, the first average non-zero intensity level being higher than the second average non-zero intensity level, and
(ii) produce a second control signal to operate the second laser to emit the second laser light with a third average non-zero intensity level for at least a portion of the first time period and with a fourth average non-zero intensity level for at least a portion of the second time period, the fourth average non-zero intensity level being higher than the second and third average non-zero intensity levels; and
a spatial light modulator optically coupled to the laser light source and configured to project an image responsive to the laser beam.

7. The light projection system of claim 6, wherein:
the laser light source further includes a third laser configured to emit third laser light in a third spectral range different from the first and second spectral ranges;
the laser controller is further configurable to produce a third control signal to operate the third laser to emit the third laser light with a fifth average non-zero intensity level for a third time period of the sequence period and with a sixth average non-zero intensity level for a fourth time period of the sequence period, fifth average non-zero intensity level being higher than the sixth average non-zero intensity level;
the third time period at least partially overlaps in time with the second time period; and
the fourth time period at least partially overlaps in time with the first time period.

8. The light projection system of claim 6,
wherein a sum of a duration of the first time period and a duration the second time period is equal to a duration of a sequence period for display of the image.

9. The light projection system of claim 6, further comprising:
a display device configured to display the image projected by the light projection system.

10. The light projection system of claim 9, wherein the laser controller is further configurable to alter at least one of the first or second control signals based on a signal from the display device to adjust the color gamut of the laser beam.

11. The light projection system of claim 6, further comprising:
at least one sensor coupled to the laser controller and the at least one sensor configured produce a sensor signal indicative of at least one parameter of the color gamut of the laser beam;
wherein the laser controller is configurable to alter, based on the sensor signal, at least one of the first or second control signals to adjust the color gamut of the laser beam.

12. The light projection system of claim 6, further comprising:
illumination optics optically coupled between the laser light source and the spatial light modulator, the illumination optics comprising a light tunnel and at least one diffuser.

13. The light projection system of claim 12, wherein the at least one diffuser comprises a static diffuser positioned between the laser light source and the light tunnel, the static diffuser configured to expand a spot size of the laser beam at the light tunnel.

14. The light projection system of claim 13, wherein the at least one diffuser further comprises a movable diffuser optically coupled between the static diffuser and the light tunnel, the movable diffuser configured to angularly expand the laser beam within a pupil of the light projection system.

15. The light projection system of claim 14, wherein the static diffuser is a first static diffuser; and
wherein the at least one diffuser further comprises a second static diffuser optically coupled between the light tunnel and the spatial light modulator, the second static diffuser configured to homogenize the laser beam within the pupil of the light projection system.

16. A method comprising:
emitting, with a first laser, first laser light in a first spectral range with a first average non-zero intensity level for a first portion of a time period and with at least a second average non-zero intensity level for a second portion of the time period, wherein the first average non-zero intensity level is higher than the second average non-zero intensity level;
emitting, with a second laser, second laser light in a second spectral range with a third average non-zero intensity level for a third portion of the time period and with at least a fourth average non-zero intensity level for a fourth portion of the time period, wherein the third average non-zero intensity level is higher than the second and fourth average non-zero intensity levels, wherein the third portion of the time period at least partially overlaps with the second portion of the time period; and
emitting, with a third laser, third laser light in a third spectral range with a fifth average non-zero intensity level for a fifth portion of the time period and with at least a sixth average non-zero intensity level for a sixth portion of the time period, wherein the fifth average non-zero intensity level is higher than the second, fourth, and sixth average non-zero intensity levels, wherein the fifth portion of the time period at least partially overlaps with the second and fourth portions of the time period.

17. The method of claim 16, wherein emitting the second laser light comprises:
emitting the second laser light with the fourth average non-zero intensity level while emitting the first laser light with the first intensity level; and
emitting the second laser light with a seventh intensity level higher than the fourth intensity level and lower than third intensity level while emitting the third laser light with the fifth intensity level.

18. The method of claim 16, wherein a duration of the time period is below a critical flicker fusion threshold of the multi-color laser light source.

19. The method of claim 16, wherein emitting the first laser light comprises emitting green laser light;
wherein emitting the second laser light comprises emitting red laser light; and
wherein emitting the third laser light comprises emitting blue laser light.

20. The method of claim 16, wherein:
a sum of durations of the first and second portions of the time period is equal to a duration of the time period;
a sum of durations of the third and fourth portions of the time period is equal to the duration of the time period; and
a sum of durations of the fifth and sixth portions of the time period is equal to the duration of the time period.
